(19) United States
(12) Patent Application Publication
(10) Pub. No.: US 2024/0105674 A1
(43) Pub. Date: Mar. 28, 2024

(54) BONDED STRUCTURE AND METHOD OF FORMING SAME

(71) Applicant: ADEIA SEMICONDUCTOR BONDING TECHNOLOGIES INC., San Jose, CA (US)

(72) Inventors: Cyprian Emeka Uzoh, San Jose, CA (US); Thomas Workman, San Jose, CA (US)

(21) Appl. No.: 18/461,372

(22) Filed: Sep. 5, 2023

Related U.S. Application Data
(60) Provisional application No. 63/374,869, filed on Sep. 7, 2022.

(51) Int. Cl. H01L 23/00

(52) U.S. Cl. CPC H01L 24/80; H01L 24/05; H01L 24/08; H01L 2224/05647; H01L 2224/08145; H01L 2224/80031; H01L 2224/80047; H01L 2224/80365; H01L 2224/80379; H01L 2224/80896; H01L 2924/04642; H01L 2924/0504; H01L 2924/0544; H01L 2924/059

(57) ABSTRACT

Bonded structures and methods of forming a bonded structure are disclosed. A bonded structure can include a first element and a second element. The first element includes a first non-conductive field region and a first conductive feature. The second element includes a second non-conductive field region and a second conductive feature. The second element is directly bonded to the first element along a bonding interface such that the first non-conductive field region is directly bonded to the second non-conductive field region without an intervening adhesive, and the first conductive feature is directly bonded to the second conductive feature without an intervening adhesive. A first portion of the first non-conductive field region at the bonding interface has a first surface roughness and a second portion of the first non-conductive field region at the bonding interface has a second surface roughness. The second surface roughness can be different from the first surface roughness. The first surface roughness can be greater than 6 Å rms.

### CROSS-REFERENCE TO RELATED APPLICATIONS

This application claims priority to U.S. Provisional Patent Application No. 63/374,869, filed Sep. 7, 2022, the entire contents of which are incorporated by reference in their entirety and for all purposes.

### BACKGROUND

### Field

The field relates to bonded structures and methods of forming a bonded structure.

### Description of the Related Art

Semiconductor elements, such as integrated device dies or chips, may be mounted or stacked on other elements thereby forming a bonded structure. For example, a semiconductor element can be mounted to a carrier, such as a package substrate, an interposer, a reconstituted wafer or element, etc. As another example, a semiconductor element can be stacked on top of another semiconductor element, e.g., a first integrated device die can be stacked on a second integrated device die. Each of the semiconductor elements can have conductive pads for mechanically and electrically bonding the semiconductor elements to one another. There is a continuing need for improved methods for forming the bonded structure.

### BRIEF DESCRIPTION OF THE DRAWINGS

Specific implementations will now be described with reference to the following drawings, which are provided by way of example, and not limitation.

FIG. 1A is a schematic cross sectional side view of two elements prior to bonding.

FIG. 1B is a schematic cross sectional side view of the two elements shown in FIG. 1A after bonding.

FIG. 2A is a scanning acoustic microscopy (CSAM) image of bonded structures.

FIG. 2B is an enlarged view of a bonded structure of the image of FIG. 1A having an occluded void.

FIG. 3A is a schematic cross sectional side view of a host element and six different elements during a bonding process.

FIGS. 3B-3E are schematic diagrams showing bonding waves between an element and the bonding surface of the host element.

FIGS. 4A-4D illustrate steps in a method of forming a roughened surface according to an embodiment.

FIG. 4E is a schematic cross sectional side view of a bonded structure according to an embodiment.

FIG. 4F is a schematic cross sectional side view of a bonded structure according to another embodiment.

FIGS. 5A-5B illustrate steps in a method of forming a roughened surface according to another embodiment.

FIG. 6A is a schematic cross sectional side view of an element with a protective layer.

FIG. 6B is a schematic cross sectional side view of singulated elements with the protective layer.

FIG. 6C is a schematic cross sectional side view of singulated elements of FIG. 6B without the protective layer.

### DETAILED DESCRIPTION OF THE PREFERRED EMBODIMENT

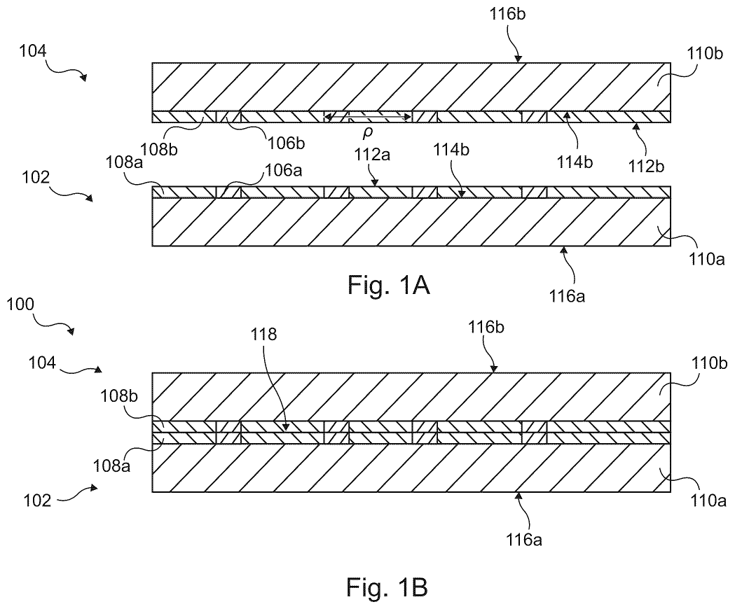

Various embodiments disclosed herein relate to directly bonded structures in which two or more elements can be directly bonded to one another without an intervening adhesive. FIGS. 1A and 1B schematically illustrate a process for forming a directly bonded structure without an intervening adhesive according to some embodiments. In FIGS. 1A and 1B, a bonded structure 100 comprises two elements 102 and 104 that can be directly bonded to one another without an intervening adhesive. Two or more semiconductor elements (such as integrated device dies, wafers, etc.) 102 and 104 may be stacked on or bonded to one another to form the bonded structure 100. Conductive features 106a (e.g., contact pads, exposed ends of vias (e.g., TSVs), or a through substrate electrodes) of a first element 102 may be electrically connected to corresponding conductive features 106b of a second element 104. Any suitable number of elements can be stacked in the bonded structure 100. For example, a third element (not shown) can be stacked on the second element 104, a fourth element (not shown) can be stacked on the third element, and so forth. Additionally or alternatively, one or more additional elements (not shown) can be stacked laterally adjacent one another along the first element 102. In some embodiments, the laterally stacked additional element may be smaller than the second element. In some embodiments, the laterally stacked additional element may be two times smaller than the second element.

In some embodiments, the elements 102 and 104 are directly bonded to one another without an adhesive. In various embodiments, a non-conductive field region that includes a non-conductive or dielectric material can serve as a first bonding layer 108a of the first element 102 which can be directly bonded to a corresponding non-conductive field region that includes a non-conductive or dielectric material serving as a second bonding layer 108b of the second element 104 without an adhesive. The non-conductive bonding layers 108a and 108b can be disposed on respective front sides 114a and 114b of device portions 110a and 110b, such as a semiconductor (e.g., silicon) portion of the elements 102, 103. Active devices and/or circuitry can be patterned and/or otherwise disposed in or on the device portions 110a and 110b. Active devices and/or circuitry can be disposed at or near the front sides 114a and 114b of the device portions 110a and 110b, and/or at or near opposite backsides 116a and 116b of the device portions 110a and 110b. The non-conductive material can be referred to as a non-conductive bonding region or bonding layer 108a of the first element 102. In some embodiments, the non-conductive bonding layer 108a of the first element 102 can be directly bonded to the corresponding non-conductive bonding layer 108b of the second element 104 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 108a and/or 108b can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SICOH dielectrics, silicon carbonitride or diamond-like carbon or a material comprising of a diamond surface. Such carbon-containing ceramic materials can be considered inorganic, despite the inclusion of carbon. In some embodiments, the dielectric materials do not comprise polymer materials, such as epoxy, resin or molding materials.

In various embodiments, direct hybrid bonds can be formed without an intervening adhesive. For example, nonconductive bonding surfaces 112a and 112b can be polished to a high degree of smoothness. The bonding surfaces 112a and 112b can be cleaned and exposed to a plasma and/or etchants to activate the surfaces 112a and 112b. In some embodiments, the surfaces 112a and 112b can be terminated with a species after activation or during activation (e.g., during the plasma and/or etch processes). Without being limited by theory, in some embodiments, the activation process can be performed to break chemical bonds at the bonding surfaces 112a and 112b, and the termination process can provide additional chemical species at the bonding surfaces 112a and 112b that improves the bonding energy during direct bonding. In some embodiments, the activation and termination are provided in the same step, e.g., a plasma to activate and terminate the surfaces 112a and 112b. In other embodiments, the bonding surfaces 112a and 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Further, in some embodiments, the bonding surfaces 112a and 112b can be exposed to fluorine. For example, there may be one or multiple fluorine peaks at or near a bonding interface 118 between the first and second elements 102, 104. Thus, in the directly bonded structure 100, the bonding interface 118 between two non-conductive materials (e.g., the bonding layers 108a and 108b) can comprise a very smooth interface with higher nitrogen content and/or fluorine peaks at the bonding interface 118. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive features 106a of the first element 102 can also be directly bonded to corresponding conductive features 106b of the second element 104. For example, a hybrid bonding technique can be used to provide conductor-to-conductor direct bonds along the bond interface 118 that includes covalently direct bonded non-conductive-to-non-conductive (e.g., dielectric-to-dielectric) surfaces, prepared as described above. In various embodiments, the conductor-to-conductor (e.g., conductive feature 106a to conductive feature 106b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, non-conductive (e.g., dielectric) bonding surfaces 112a, 112b (for example, inorganic dielectric surfaces) can be prepared and directly bonded to one another without an intervening adhesive as explained above. Conductive contact features (e.g., conductive features 106a and 106b which may be at least partially surrounded by non-conductive dielectric field regions within the bonding layers 108a, 108b) may also directly bond to one another without an intervening adhesive. In various embodiments, the conductive features 106a, 106b can comprise discrete pads or traces at least partially embedded in the non-conductive field regions. In some embodiments, the conductive contact features can comprise exposed contact surfaces of through substrate vias (TSVs). In some embodiments, the respective conductive features 106a and 106b can be recessed below exterior (e.g., upper) surfaces (non-conductive bonding surfaces 112a and 112b) of the dielectric field region or non-conductive bonding layers 108a and 108b, for example, recessed by less than 30 nm, less than 20 nm, less than 15 nm, or less than 10 nm, for example, recessed in a range of 2 nm to 20 nm, or in a range of 4 nm to 10 nm. In various embodiments, prior to direct bonding, the recesses in the opposing elements can be sized such that the total gap between opposing contact pads is less than 15 nm, or less than 10 nm. The non-conductive bonding layers 108a and 108b can be directly bonded to one another without an adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or DBI®, techniques commercially available from Xperi of San Jose, CA, can enable high density of conductive features 106a and 106b to be connected across the direct bond interface 118 (e.g., small or fine pitches for regular arrays). In some embodiments, the pitch of the conductive features 106a and 106b, such as conductive traces embedded in the bonding surface of one of the bonded elements, may be less than 100 microns or less than 10 microns or even less than 2 microns. For some applications, the ratio of the pitch of the conductive features 106a and 106b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 106a and 106b and/or traces can comprise copper, although other metals may be suitable.

Thus, in direct bonding processes, a first element 102 can be directly bonded to a second element 104 without an intervening adhesive. In some arrangements, the first element 102 can comprise a singulated element, such as a singulated integrated device die. In other arrangements, as shown in FIGS. 1A and 1B, the first element 102 can comprise a carrier or substrate (e.g., a wafer) that includes a plurality (e.g., tens, hundreds, or more) of device regions that, when singulated, form a plurality of integrated device dies. Similarly, the second element 104 can comprise a singulated element, such as a singulated integrated device die, as shown in FIGS. 1A and 1B. In other arrangements, the second element 104 can comprise a carrier or substrate (e.g., a wafer). The embodiments disclosed herein can accordingly apply to wafer-to-wafer, die-to-die, or die-to-wafer bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the singulation process (e.g., saw markings if a saw singulation process is used).

As explained herein, the first and second elements 102 and 104 can be directly bonded to one another without an adhesive, which is different from a deposition process. In one application, a width of the first element 102 in the bonded structure is similar to a width of the second element 104. In some other embodiments, a width of the first element 102 in the bonded structure 100 is different from a width of the second element 104. Similarly, the width or area of the larger element in the bonded structure may be at least 10% larger than the width or area of the smaller element. The first and second elements 102 and 104 can accordingly comprise non-deposited elements. Further, directly bonded structures 100, unlike deposited layers, can include a defect region along the bond interface 118 in which nanometer-scale voids (nanovoids) are present. The nanovoids may be formed due to activation of the bonding surfaces 112a and 112b (e.g., exposure to a plasma). As explained above, the bond interface 118 can include concentration of materials from the activation and/or last chemical treatment processes. For example, in embodiments that utilize a nitrogen plasma for activation, a nitrogen peak can be formed at the bond interface 118. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolized (OH-terminated) surface with NH2 molecules, yielding a nitrogen-terminated surface. In embodiments that utilize an oxygen plasma for activation, an oxygen peak can be formed at the bond interface 118. In some embodiments, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a and 108b can also comprise polished surfaces that are planarized to a high degree of smoothness.

In various embodiments, the metal-to-metal bonds between the contact pads 106a and 106b can be joined such that copper grains grow into each other across the bond interface 118. In some embodiments, the copper can have grains oriented along the 111 crystal plane for improved copper diffusion across the bond interface 118. The bond interface 118 can extend substantially entirely to at least a portion of the bonded conductive features 106a and 106b, such that there is substantially no gap between the non-conductive bonding layers 108a and 108b at or near the bonded conductive features 106a and 106b. In some embodiments, a barrier layer may be provided under the conductive features 106a and 106b (e.g., which may include copper). In other embodiments, however, there may be no barrier layer under the conductive features 106a and 106b, for example, as described in U.S. Pat. No. 11,195,748, which is incorporated by reference herein in its entirety and for all purposes.

Beneficially, the use of the hybrid bonding techniques described herein can enable extremely fine pitch between adjacent contact pads 106a and 106b, and/or small pad sizes. For example, in various embodiments, the pitch p (i.e., the distance from edge-to-edge or center-to-center, as shown in FIG. 1A) between adjacent conductive features 106a (or 106b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

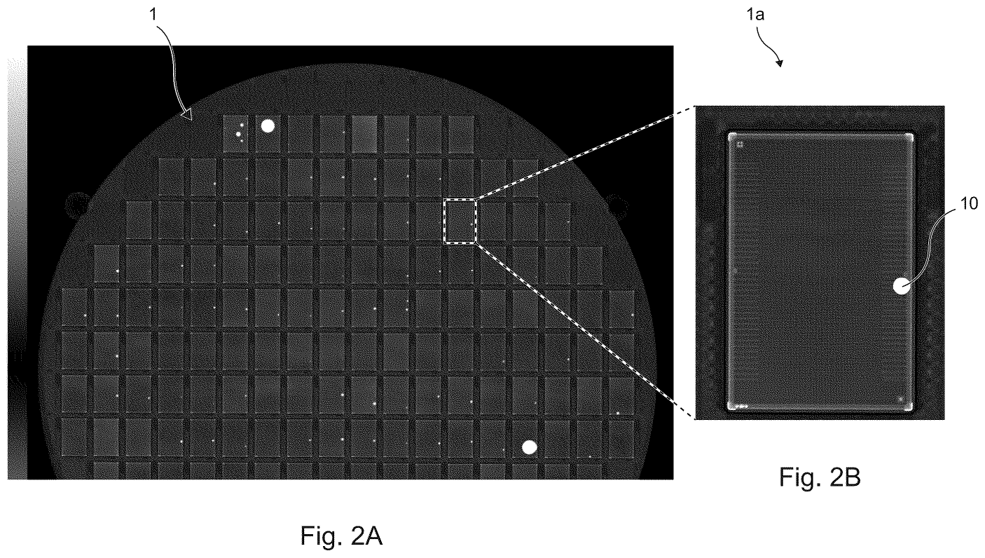

FIG. 2A is a scanning acoustic microscopy (CSAM) image of bonded structures 1. FIG. 2B is an enlarged view of a bonded structure 1a of the image of FIG. 1A having an occluded void 10. The occluded void 10 may inhibit the joining of particular contact pads in the vicinity, creating openings or other failures in the bond. For example, any void larger than the pad diameter and/or pitch can potentially create an opening and hybrid bond failure. There are various reasons that a void may be present in a bonded structure. For example, an unevenly or non-uniformly propagated bonding wave during the contact of a surface of an element to a surface of another element may cause the void in a bonded structure.

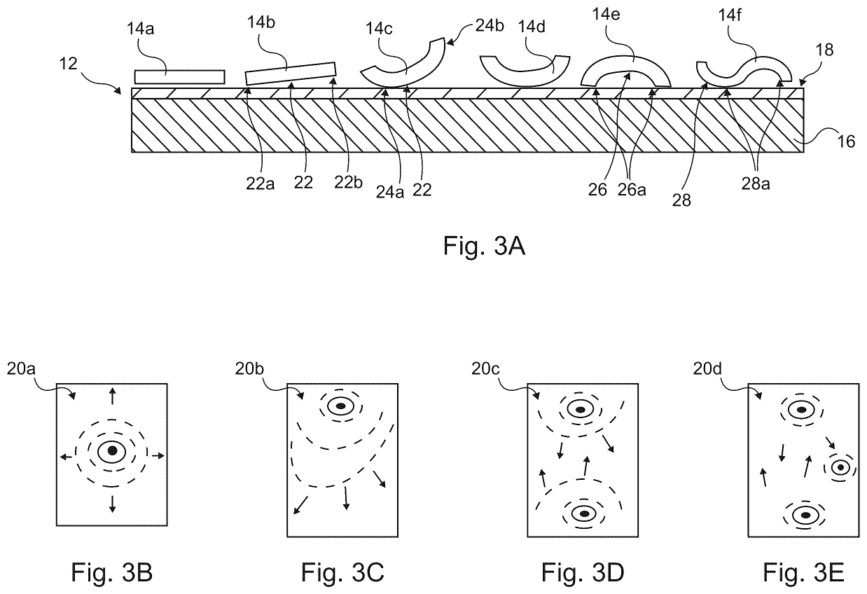

FIG. 3A is a schematic cross sectional side view of a host element 12 and six different elements 14a, 14b, 14c, 14d, 14e, 14f having different warpage profile before a bonding process. The host element 12 can include a substrate 16 and a bonding surface 18. The substrate 16 can comprise a device portion, such as a semiconductor (e.g., silicon) portion. For example, the host element 12 can comprise the first element 102, and the elements 14a, 14b, 14c, 14d, 14e, 14f can comprise second elements 104 that are to be directly bonded to the first element 102. The elements 14a-14f are configured to directly bond to the bonding surface 18 of the host element 12. In general, it is preferable that the second element 104 is flat, with relatively low warpage. In practice, the second elements 104 (e.g., the elements 14a to 140 can exhibit large variations in warpage and/or a warpage profile as illustrated in FIG. 3A. Depending, for example, on the fabrication processes, the variation of the warpage of the second elements 104 may range between ±5 μm to ±300 μm. The profile of the surface of the warped second element 104 with respect to the planar bonding surface 18 of the host element 12 may be concave, convex, saddle or the combinations thereof. In some embodiments, the elements 14a-14f can comprise integrated device dies.

The element 14a is being provided on the bonding surface 18 of the host element 12. The element 14a can have a flat shape with a warpage of less than ±40 μm. For example, the element 14a can comprise a die with a thickness in a range of 40 μm to 100 μm, and have a flat shape with a warpage of less than ±20 μm. The die can have a width of about 8 mm and a length of about 10 mm, for example. For example, element 14a can be provided on the bonding surface 18 with a surface of the element 14a being generally parallel with the bonding surface 18. In some embodiments, during a bonding operation, the bonding head of the bonding tool (not shown) picks the element 14a from the backside opposite the bonding surface of the element 14a. The element 14a may be adapted on the bonding head such that the center of the element 14a first makes contact with the bonding surface 18 of the host element 12. The initial contact of the center of element 14a on the bonding surface 18 promotes a more even or uniform outward radial propagation of the bonding wave or waves from the center region of the element 14a outwardly towards the peripheries of the element 14a. The propagation of contact across the bonding surface can be referred to as the bonding wave.

The element 14d has a convexly warped shape. For example, the element 14d is convexly warped relative to the generally flat, straight element 14a. The element 14d is being provided on the bonding surface 18 of the host element 12. The element 14d can be provided on the bonding surface 18 such that the element 14d makes contact with the bonding surface 18 of the host element 12 from the center of the element 14d to peripheries or edges of the element 14d. The bonding wave between the element 14d and the host element 12 can propagate from the initial center contact region between element 14d and host element 12 to the peripheries or edge of element 14d.

FIG. 3B is a schematic diagram showing the bonding wave 20a between an element (e.g., the elements 14a, 14d) and the bonding surface 18 of the host element 12. The bonding wave 20a indicates that the element 14a makes contact and bonds with the bonding surface 18 of the host element 12 from the center of the element 14a to edges of the element 14a.

The element 14b has the same or generally similar flat shape as the element 14a. The element 14b is being provided on the bonding surface 18 of the host element 12. The element 14b can be provided on the bonding surface 18 such that the element 14b makes contact with the bonding surface 18 of the host element 12 from a first edge portion 22a at or near a first edge of a surface 22 of the element 14b to a second edge portion 22b at or near a second edge of the surface 22 of the element 14b opposite the first edge portion 22a. For example, the surface 22 of the element 14b can be angled relative to the bonding surface 18 of the host element 12 at initial contact. In some embodiments, the angle between the surface 22 and the bonding surface 18 at initial contact can be in a range between 1° and 15°, 3° and 15°, 5° and 15°, 10° and 15°, 3° and 10°, or 5° and 10°. The bonding wave can propagate progressively outwards from the first edge portion 22a to the second edge portion 22b of the surface 22 of the element 14b opposite the first edge portion 22a. The angle between the surface 22 and the bonding surface 18 can be smaller as the bonding wave propagates. In some embodiments, the first edge portion 22a can include a portion that is within 5%, 10% or 20% of a length of the element 14b (defined by a distance between the first and second edges) from the first edge.

The element 14c has a convexly warped shape. For example, the element 14c is convexly warped relative to the generally flat, straight element 14a. The element 14c is being provided on the bonding surface 18 of the host element 12. The element 14c can be provided on the bonding surface 18 such that the element 14c makes contact with the bonding surface 18 of the host element 12 from a first portion 24a of a surface 24 of the element 14c to a second portion 24b of the surface 24 of the element 14c opposite the first portion 24a. The bonding wave can propagate progressively outwards from the first portion 24a to the second portion 24b of the surface 24 of the element 14c opposite the first portion 24a. The first portion 24a can comprise a portion of the element near an edge of the surface 24. For example, the first portion 24a can comprise a portion between the edge of the surface 24 and a center of the surface 24. In some embodiments, the bonding wave can propagate in opposite directions away from each other, when the first portion 24a of element 14c is located between an edge and the center of element 14a.

FIG. 3C is a schematic diagram showing a bonding wave 20b between an element (e.g., the elements 14b, 14c) and the bonding surface 18 of the host element 12. The bonding wave 20b indicates that the element 14b, 14c makes contact and bond with the bonding surface 18 of the host element 12 from one side portion to the other.

The element 14e has a concavely warped shape. For example, the element 14 is concavely warped relative to the generally flat, straight element 14a. The element 14e is being provided on the bonding surface 18 of the host element 12. The element 14e can be provided on the bonding surface 18 such that the element 14e makes contact with the bonding surface 18 of the host element 12 from edge portions 26a of a surface 26 of the element 14e to other portions (e.g., interior portions) of the surface 26 of the element 14e.

The element 14f comprises a saddle surface. For example, the element 14 is saddled relative to the generally flat, straight element 14a. The element 14f is being provided on the bonding surface 18 of the host element 12. The element 14f can be provided on the bonding surface 18 such that the element 14f can make contact with the bonding surface 18 of the host element 12 from portions 28a of a surface 28 of the element 14e to other portions of the surface 28 of the element 14f.

FIG. 3D is a schematic diagram showing a bonding wave 20c between an element (e.g., the elements 14e, 140 and the bonding surface 18 of the host element 12. The bonding wave 20c indicates that the element 14e, 14f makes contact and bonds with the bonding surface 18 of the host element 12 from multiple (e.g., two) contact points to other locations. In some embodiments, with multiple initial contact portions (e.g., the edge portions 26a of the element 14e and the portions 28a of the element 140, the bonding waves can propagate towards each other. The interaction of the multiple bonding waves may occlude or wrap around a portion of the element (e.g., the elements 14e, 140 and/or the host element 12 thereby trapping a patch of air, resulting in a void in the bonding interface between the element (e.g., the elements 14e, 140 and the host element 12.

FIG. 3E is a schematic diagram showing a bonding wave 20d between an element (e.g., the elements 14e, 140 and the bonding surface 18 of the host element 12. The bonding wave 20d indicates that the element 14e, 14f makes contact with the bonding surface 18 of the host element 12 from multiple (e.g., three) contact portions or points to other locations. With multiple initial first contact portions, competing multiple bonding waves are generated between the element (e.g., the elements 14e, 140 and the host element 12. Portions of the competing multiple waves can propagate towards each other. The interaction of the competing multiple bonding waves may occlude or wrap around a portion of the element (e.g., the elements 14e, 140 and/or the host element 12 thereby trapping a patch of air, resulting in a void in the bonded first and second elements.

An element with a curved or warped shape may have more uneven or non-uniform bonding wave propagation that can increase the chance of forming a void between the bonded elements as compared with an element having a completely or generally straight surface or relatively low warpage. Such uneven or non-uniform bonding wave propagation can increase the chance of forming a void between bonded elements that can be problematic (e.g., a void with a void size larger than a pad diameter and/or pitch of conductive features). For example, a relatively large bonding void disposed between pads or conductive features in bonded element 102 and 104, disrupts electrical signal between the opposing conductive features; thus forming an open circuit. Such undesired open circuits lead to lower electric device yield in the bonded elements 102 and 104. The poor yielding devices may lead to a revenue loss. A thinner element may tend to have more curvature(s) and warpage than a thicker element, which in turn can increase the likelihood of voids being formed due to non-uniform bonding wave propagation.

Various embodiments disclosed herein relate to controlling the propagation of a bonding wave thereby reducing the likelihood of or preventing formation of a void between bonded elements of a bonded structure. Various embodiments disclosed herein can improve manufacturing yield and device reliability. The propagation of a bonding wave can be controlled by modifying a bonding speed at which the elements are directly bonded.

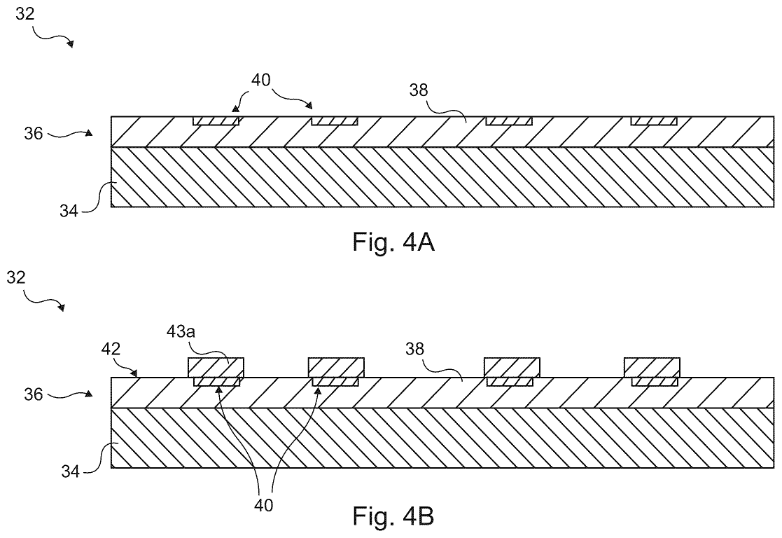

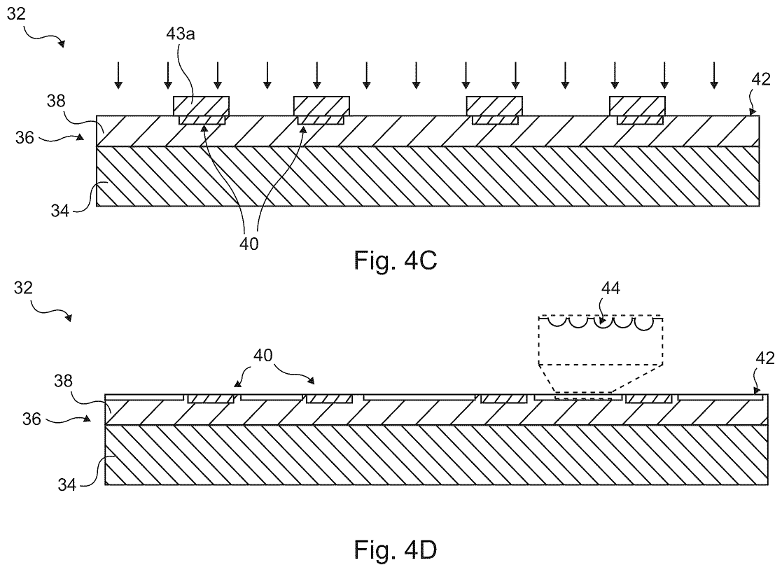

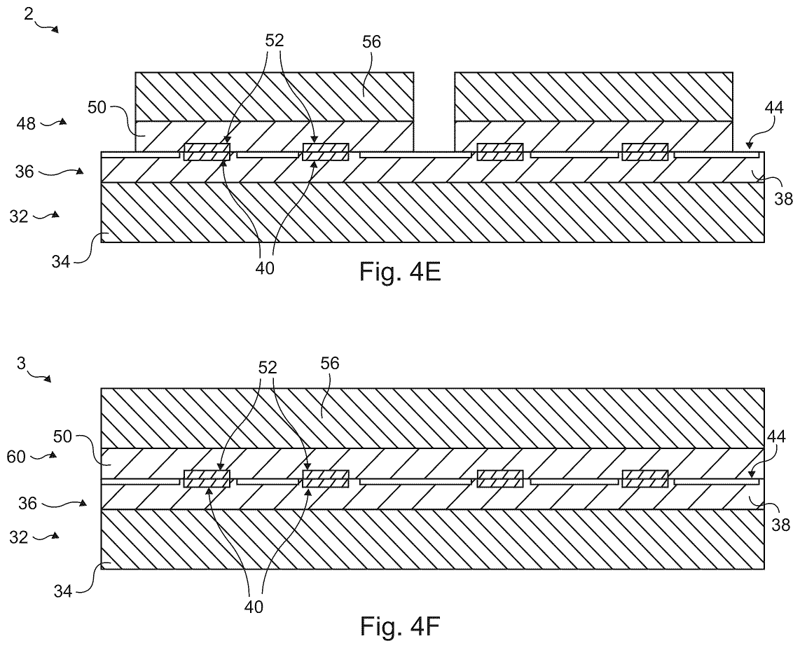

FIGS. 4A-4F illustrate various steps of forming bonded structures 2, 3. FIG. 4A is a schematic cross sectional side view of a first element 32. The first element 32 can include a device portion 34, such as a semiconductor (e.g., silicon) portion having circuitry patterned therein, and a bonding layer 36 over the device portion 34. The bonding layer 36 can include a non-conductive field region 38 and conductive features 40 spaced apart by portions of the non-conductive field region 38 and at least partially embedded in the non-conductive field region 38. The bonding layer 36 may comprise multiple metallization layers as found in back end of line (BEOL) or packaging redistribution layers. A bonding surface 42 of the first element 32 can be prepared for direct bonding as explained above. For example, the bonding surface 42 of the first element 32 can be polished to a high degree of smoothness in preparation for direct bonding. In some embodiments, the roughness of the polished non-conductive field region 38 can be less than 15 Å rms, less than 10 Å rms, or less than 5 Å rms. The non-conductive field region 38 can also include signatures of activation and/or termination for direct bonding, such as fluorine and nitrogen profiles, as described above.

In FIG. 4B, a patterned masking structure (e.g., a resist layer 43a) can be provided over the bonding surface 42 of the first element 32. In some embodiments, the resist layer 43a can comprise a photoresist layer. The resist layer 43a can be patterned such that at least the conductive features 40 are covered by the photoresist layer 43a. In some embodiments, the resist layer 43a can at least partially cover a portion of the non-conductive field region 38 proximate the conductive feature 40. For example, portions of the non-conductive field region 38 around the conductive features 40 can be covered with resist layer 43a.

In some embodiments, the masking structure comprise a passivation layer. For example, the resist layer 43a can comprise benzotriazole (BTA), deposited from a 10 ppm to 100 ppm BTA solution. The BTA solution can be sprayed on the bonding surface 42 of the first element 32 before, for example, spin drying the first element 32. When the BTA solution is used as the resist layer 43a, resist layer 43a can be selectively formed over the conductive features 40. In some embodiments, the masking structure can comprise a multilayer structure, such as a combination of a resist layer and a passivation layer. The resist layer 43a disclosed herein is an example of a masking structure, and the resist layer 43a in various embodiments can be replaced with the passivation layer.

In FIG. 4C, portions of the polished non-conductive field region 38 can be selectively roughened. In some embodiments, the non-conductive field region 38 can be roughened by way of an etching process, such as a wet etch or reactive ion etching (RIE). The arrows in FIG. 4C can represent flow of the etchant.

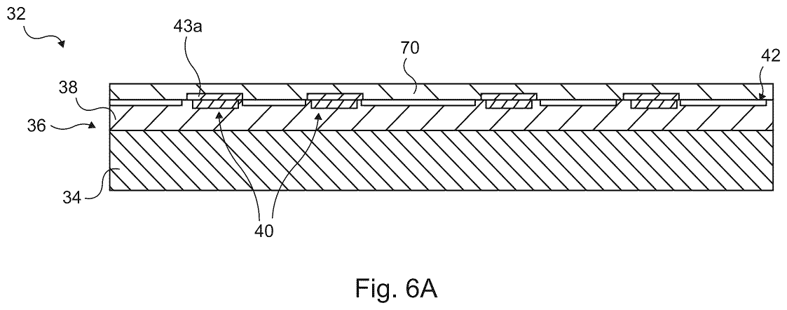

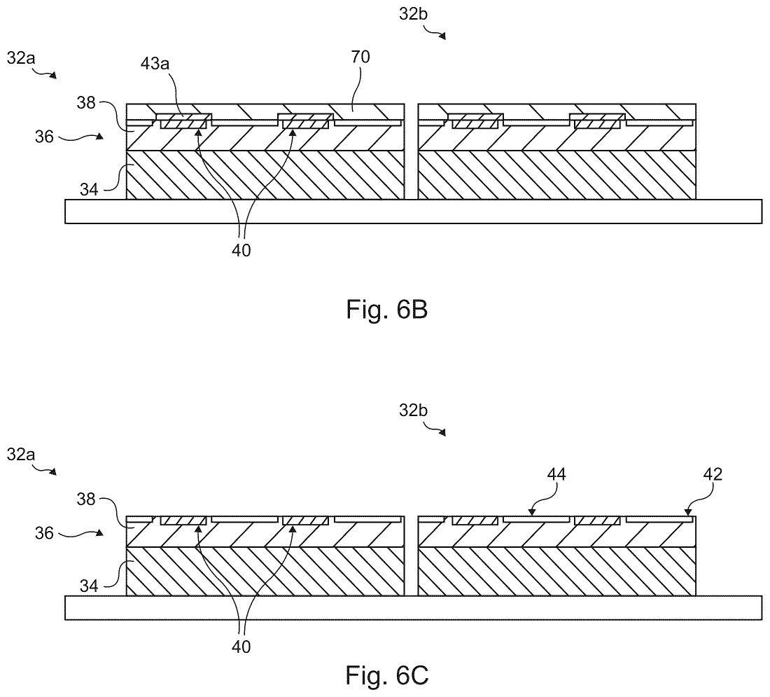

FIG. 4D shows the first element 32 having a non-conductive field region 38 selectively provided with a roughened surface 44. The resist layer 43a has been removed from the bonding surface 42 of the first element 32 in FIG. 4D. In some embodiments, the resist layer 43a can be removed with a removing agent, such as a photoresist removing solvent or a recommended developer by the supplier of the resist. For example, the resist layer 43a can be removed by a combination of plasma resist strip and a developer wet cleaning process. When the passivation layer is used as the masking structure as described above, for example, an alkaline chemical may be used to remove the passivation layer. After roughening the non-conductive bonding surface 38, the bonding surface of first element 32 can be cleaned to remove contaminants. The resist forming and removal process should not significantly degrade the smoothness or excessively etch the conductive features as to impair the conductive features. For example, the resist forming and resist removal steps should not increase the recess on the conductive features beyond the recommended specification for conductive features recess. In some embodiments, the resist layer 43a can be removed at a later stage before bonding another element to the first element 32 (see FIGS. 6A-7C). In some embodiments, the first element 32 may comprise a wafer for a wafer to wafer (W2W) bonding operation. In other embodiments, cleaned first element 32 may be mounted on a dicing frame for singulation operations. The singulation process may include coating the first element 32 with a protective layer before the sinulation process.

The roughened surface 44 can have a surface roughness that is rougher than the surface roughness of the non-conductive field region 38 after the polishing step but before the roughening process. The roughness can be controlled by adjusting the intensity, chemistry, and/or duration of the roughening process. In some embodiments, the roughened surface 44 may be roughened relative to the polished surface (e.g., the roughened surface 44 may have a roughness that is rougher than the polished surface) but can have a surface roughness that is sufficiently smooth for a direct bonding. For example, the roughened surface 44 can have a surface roughness of at least 10 Å rms, at least 15 Å rms, or at least 20 Å rms, for example a surface roughness in a range of 6 Å rms to 100 Å rms, 6 Å rms to 60 Å rms, 10 Å rms to 40 Å rms, 10 Å rms to 100 Å rms, 10 Å rms to 60 Å rms, 15 Å rms to 30 Å rms, 25 Å rms to 100 Å rms, 35 Å rms to 200 Å rms, 35 Å rms to 100 Å rms, 55 Å rms to 200 Å rms, 55 Å rms to 100 Å rms, 75 Å rms to 200 Å rms, 75 Å rms to 100 Å rms, or 100 Å rms to 200 Å rms.

FIG. 4E is a schematic cross sectional side view of the bonded structure 2 according to an embodiment. The bonded structure 2 can include the first element 32 and one or more elements including a second element 48 stacked over the first element 32. In some embodiments, the first element 32 can comprise a wafer and the second element 48 can comprise an integrated device die. In some other embodiments, the first element 32 can comprise an integrated device die and the second element 48 can comprise another integrated device die. The second element 48 can include a non-conductive field region 50, conductive features 52 spaced apart by at least a portion of the non-conductive field region 50, and a device portion 56. Portions of the non-conductive field region 50 of the second element 48 can be bonded to corresponding portions of the nonconductive field region 38 of the first element 32. The conductive features 52 of the second element 48 can be bonded to corresponding conductive features 40 of the first element 32. For example, the portions of the non-conductive field region 50 can be directly bonded to corresponding portions of the nonconductive field region 38 without an intervening adhesive, and the conductive features 52 can be directly bonded to corresponding conductive features 40 without an intervening adhesive.

The roughened surface 44 can contribute to changing a bonding contact area, bond energy, and a speed of the bonding. For example, the roughened surface 44 enables the first and second elements 32, 48 to have reduced bonding contact area, reduced bond energy, and reduced bonding wave propagation times or speed as compared to elements that include only smooth surface. Such reduction in bonding contact area, bond energy, and bond speed can contribute to reducing the chance of void formation due to curvature and/or warpage of an element.

The roughened surface 44 enables the portions of the non-conductive field region 50 and the corresponding portions of the nonconductive field region 38 to be directly bonded with a sufficient strength to enable direct hybrid bonding between the first and second elements 32, 48. In some embodiments, a bond strength between the non-conductive field region 50 and the nonconductive field region 38 can be in a range of, for example, 500 mJ/cm² to 2500 mJ/cm², 750 mJ/cm² to 2000 mJ/cm², 1000 mJ/cm² to 1500 mJ/cm², 500 mJ/cm² to 1250 mJ/cm², 500 mJ/cm² to 1000 mJ/cm², 500 mJ/cm² to 750 mJ/cm², 750 mJ/cm² to 1250 mJ/cm², or 750 mJ/cm² to 1000 mJ/cm².

FIG. 4F is a schematic cross sectional side view of the bonded structure 3 according to an embodiment. The bonded structure 3 can include the first element 32 and a second element 60. In some embodiments, the first element 32 can comprise a wafer and the second element 60 can comprise another wafer. The second element 60 can include a non-conductive field region 50, conductive features 52 spaced apart by at least a portion of the non-conductive field region 50, and a device portion 56. Portions of the non-conductive field region 50 of the second element 60 can be bonded to corresponding portions of the nonconductive field region 38 of the first element 32. The conductive features 52 of the second element 60 can be bonded to corresponding conductive features 40 of the first element 32. For example, the portions of the non-conductive field region 50 can be directly bonded to corresponding portions of the nonconductive field region 38 without an intervening adhesive, and the conductive features 52 can be directly bonded to corresponding conductive features 40 without an intervening adhesive.

The roughened surface 44 enables the portions of the non-conductive field region 50 and the corresponding portions of the nonconductive field region 38 to be directly bonded with a sufficient strength to enable direct hybrid bonding between the first and second elements 32, 60. In some embodiments, a bond strength between the non-conductive field region 50 and the nonconductive field region 38 can be in a range of, for example, 500 mJ/cm² to 1500 mJ/cm², 750 mJ/cm² to 1500 mJ/cm², 1000 mJ/cm² to 1500 mJ/cm², 500 mJ/cm² to 1250 mJ/cm², 500 mJ/cm² to 1000 mJ/cm², 500 mJ/cm² to 750 mJ/cm², 750 mJ/cm² to 1250 mJ/cm², or 750 mJ/cm² to 1000 mJ/cm².

In some embodiments, the second element 48, 60 can have a bonding surface that is the same as or generally similar to the bonding surface 42 of the first element 32. In some embodiments, the second element 48, 60 can have a bonding surface that is formed in the same or a generally similar method as those disclosed herein with respect to the first element 32. After the bonding operation, the bonded structure 3 can be thermally processed or annealed at a higher temperature or temperatures (150 to 400° C. between 10 miutes to up to 10 hours) to increase the bond strength of the bonded non-conductive interface region and the metallurgical bonding of the opposing respective conductive feature of elements 32, 60 in a suitable oven. The cooled bonded structure 3 may be singulated for other subsequent operations. For example, the singulation process may include coating the bonded structure 3 with a protective layer, mounting the coated bonded structure 3 on a dicing frame prior to singulation.

In the bonded structures 2, 3, the surface roughness of the first element 32 and the surface roughness of the second element 48, 60 can be inspected. For example, the surface roughnesses can be measured through a transmission electron microscopy (TEM) image of a bonding interface of a cross section of the bonded structure. In the TEM image a seam (e.g., a dielectric seam) may be observed between the bonded non-conductive field regions. The surface roughnesses of the non-conductive field regions 38, 50 may not significantly change before and after bonding.

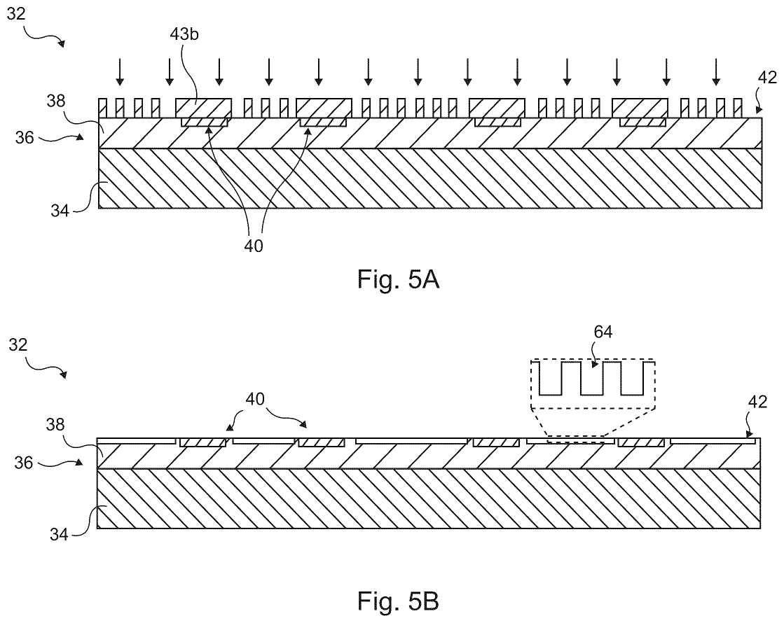

The roughening process described with respect to FIGS. 4B-4D may be replaced with any suitable process to roughen the bonding surface 42. For example, FIGS. 5A, and 5B show an alternative or additional roughening processes.

FIG. 5A is a schematic cross sectional side view of the first element 32 with patterned resist layer 43b. In some embodiments, portions of the non-conductive field region 38 that are not covered by the resist layer 43b can be roughened by way of an etching process, such as a wet etch or reactive ion etching (RIE). The arrows in FIG. 5A can represent flow of the etchant. Portions of the non-conductive field region 38 that are covered by the resist layer 43b can remain smooth, and the portions of the non-conductive field region 38 that are not covered by the resist layer 43b can be rough. In theory, keeping more smooth surface can provide a stronger bonding strength when the first element 32 is bonded to another element, as compared to a surface with more roughened surface. Therefore, the resulting bonding strength can be controlled at least in part by adjusting the areas of the bonding surface 42 to be roughened.

FIG. 5B shows the first element 32 with a roughened surface 64. The roughened surface 64 can have a surface roughness that is rougher than the surface roughness of the non-conductive field region 38 after polishing but before the roughening process. The roughness can be controlled by adjusting the intensity, chemistry, and/or duration of the roughening process. In some embodiments, the roughened surface 64 can have a surface roughness that is sufficiently smooth for a direct bonding. For example, the roughened surface 64 can have a surface roughness of at least 10 Å rms, at least 15 Å rms, or at least 20 Å rms, for example a surface roughness in a range of 6 Å rms to 100 Å rms, 6 Å rms to 60 Å rms, 10 Å rms to 40 Å rms, 10 Å rms to 100 Å rms, 10 Å rms to 60 Å rms, in a range of 6 Å rms to 500 Å rms, 6 Å rms to 200 Å rms, 10 Å rms to 200 Å rms, 25 Å rms to 200 Å rms, 30 Å rms to 200 Å rms, 35 Å rms to 200 Å rms, 50 Å rms to 200 Å rms, 100 Å rms to 200 Å rms, 6 Å rms to 100 Å rms, 6 Å rms to 25 Å rms, 25 Å rms to 100 Å rms, 35 Å rms to 100 Å rms, 55 Å rms to 200 Å rms, 55 Å rms to 100 Å rms, 75 Å rms to 200 Å rms, 75 Å rms to 100 Å rms, or 100 Å rms to 200 Å rms. In some embodiment, the depth of the roughened surface 64 with respect to a portion of the bonding surface 42 that is not roughened may range between 6 Å and 2000 Å, 10 Å and 1000 Å, or 20 Å and 200 Å, for example. A second element can be bonded to the first element 32 having the roughened surface 64.

In some embodiments, depending on the patterning, the bonding surface 42 of the non-conductive field region 38 can have smooth surface portions and roughened surface portions 64. Portions of the bonding surface 42 that are covered by the resist layer 43b can comprise the smooth surface portions (e.g., remaining portions of the polished bonding surface that have not been roughened). In some embodiments, a difference between the surface roughness of the smooth surface portions (e.g., polished surface portions) and the surface roughness of the roughened surface portions 64 can be at least 5 Å rms, 10 Å rms, 20 Å rms, 50 Å rms or 100 Å rms. For example, the bonding surface 42 can have smooth surface portions (e.g., polished portions) that have a surface roughness less than 15 Å rms, less than 10 Å rms, or less than 5 Å rms, and the roughened surface portions 64 can have a surface roughness greater than the surface roughness of the smooth surface, such as a surface roughness of at least 10 Å rms, at least 15 Å rms, or at least 20 Å rms, for example a surface roughness in a range of 6 Å rms to 60 Å rms, 10 Å rms to 40 Å rms, 10 Å rms to 100 Å rms, 10 Å rms to 60 Å rms, in a range of 6 Å rms to 500 Å rms, 6 Å rms to 200 Å rms, 10 Å rms to 200 Å rms, 25 Å rms to 200 Å rms, 30 Å rms to 200 Å rms, 35 Å rms to 200 Å rms, 50 Å rms to 200 Å rms, 100 Å rms to 200 Å rms, 6 Å rms to 100 Å rms, 6 Å rms to 25 Å rms, 25 Å rms to 100 Å rms, 35 Å rms to 100 Å rms, 55 Å rms to 200 Å rms, 55 Å rms to 100 Å rms, 75 Å rms to 200 Å rms, 75 Å rms to 100 Å rms, or 100 Å rms to 200 Å rms. In some embodiments, when the bonding surface 42 is patterned to have both the roughened surface portions 64 and the smooth surface portions, with the smooth surface portions bonding to the non-conductive field region 50 of the second element 48, 60, the majority of the bonding strength between the non-conductive field region 38 and the non-conductive field region 50 may be provided by the smooth surface portions.

In some embodiments, after a roughening process disclosed herein, a protective layer can be provided over the roughened surface and the resist layer 43a, 43b. For example, the protective layer can be provided to protect the element during a singulation process.

FIG. 6A is a schematic cross sectional side view of the first element 32 with a protective layer 70. The protective layer 70 can be provided (e.g., deposited) over the bonding surface 42 and the masking structure (e.g., the resist layer 43a). As described above, the resist layer 43a can be replaced with a suitable masking layer, such as a passivation layer. Though FIG. 6A shows the resist layer 43a which is selectively applied over contact features 40, in some other embodiments, the protective layer 70 may be provided over the bonding surface 42 and the resist layer 43b which is selectively applied over the contact features 40 and portions of the bonding surface 42 (see FIG. 5A).

In some embodiments, the protective layer 70 may comprise a material with a spin-on glass layer. The protective layer 70 can comprise an organic nonconductive material.

In some embodiments, the protective layer 70 may comprise multiple layers of different materials at different locations. For example, the protective layer 70 can have a first sub-protective over conductive features 40 and a second sub-protective layer roughened surface 44.

In FIG. 6B, the element 32 can be singulated into a plurality of singulated elements 32a, 32b (e.g., singulated dies). In some embodiments, singulation can comprise a sawing process, a laser dicing, an etching process, or any other suitable processes.

In FIG. 6C, the protective layer 70 and the resist layer 43a can be removed (e.g., stripped) from the singulated elements 32a, 32b. In some embodiments, the protective layer 70 and the resist layer 43a can be removed simultaneously. After removal of the protective layer 70 and the resist layer 43a, the bonding surface 42 that comprises the roughened surface 44 and the conductive features 40 can be exposed. The singulated elements 32a, 32b can be bonded to another element in accordance with various embodiments disclosed herein.

In some embodiments, a second protective layer can replace the resist layer 43a. The protective layer 70 and the second protective layer can be provided after removing a masking structure (e.g., a photoresist layer and/or a passivation layer) for a roughening process. In some embodiments, the second protective layer can comprise an organic nonconductive material. In some embodiments, using a material with a low coefficient of thermal expansion may be advantageous in reducing the stress on the element 32. In some embodiments, the second protective layer 72 may comprise a porous material. The protective layer 70 and the second protective layer can protect the elements 32a, 32b during a singulation process. The protective layer 70 and the second protective layer can be removed (e.g., stripped) from the singulated elements 32a, 32b. In some embodiments, the protective layer 70 and/or the second protective layer can be removed simultaneously. After removal of the protective layer 70 and/or the second protective layer, the bonding surface 42 that comprises the roughened surface 44 and the conductive features 40 can be exposed. The singulated elements 32a, 32b can be bonded to another element in accordance with various embodiments disclosed herein.

In one aspect, a method of forming a bonded structure is disclosed. The method can include polishing a surface of a first element to form a polished surface, roughening at least a portion of the polished surface of the first element to form a bonding surface having a roughened surface (for example, having a surface roughness of at least 10 Angstroms rms), and directly bonding the bonding surface of the first element to a bonding surface of a second element.

In one embodiment, the first element includes a non-conductive field region and a conductive feature at the bonding surface. Polishing the surface can include polishing the non-conductive field region to a surface roughness of 6 Å rms or less. Roughening can include roughening a portion of the non-conductive field region to a surface roughness greater than 6 Å rms. The entire polished surface of the non-conducive field region can be roughened. The second element can include a non-conductive field region and a conductive feature. The non-conductive field region of the first element and the non-conductive field region of the second element can be directly bonded to one another without an intervening adhesive. The conducive feature of the first element and the conductive feature of the second element are directly bonded to one another without an intervening adhesive.

In one embodiment, the method further includes polishing a surface of the second element to define the bonding surface of the second element.

In one embodiment, the method further includes polishing a surface of the second element to define a polished surface of the second element, and roughening at least a portion of the polished surface of the second element to define the bonding surface of the second element that includes a roughened surface.

In one embodiment, roughening the portion of the polished surface comprises patterning a masking structure over the polished surface. The masking structure can include a photoresist layer or a passivation layer. The method can further include removing the masking structure. The method can further include providing a protective layer over the roughened surface of the first element. The method can further include singulating the first element into a plurality of singulated elements and removing the protective layer from the singulated elements.

In one embodiment, directly bonding includes initially contacting an edge portion of the bonding surface of the first element to the bonding surface of the second element such that the bonding surface of the first element is angled in a range of 1° to 15° relative to the bonding surface of the second element.

In one aspect, a method of forming a bonding surface for direct bonding is disclosed. The method can include providing an element having a polished surface including a non-conductive field region and a conductive feature, and roughening at least a portion of non-conductive field region of the polished surface.

In one embodiment, the method further includes polishing a surface of the element to form the polished surface.

In one embodiment, the polished surface has a surface roughness of 6 Å rms or less.

In one embodiment, roughening the portion of the non-conductive field region comprises forming a roughened surface having a surface roughness greater than 6 Å rms.

In one embodiment, the surface roughness of the roughened surface is in a range of 35 Å rms to 200 Å rms.

In one embodiment, the method further includes patterning a masking structure over the polished surface before roughening. The method can further include removing the masking structure after roughening. The method can further include providing a masking structure over the roughened surface of the first element. The masking structure can include a photoresist layer or a passivation layer.

In one aspect, a bonded structure is disclosed. The bonded structure can include a first element that includes a first non-conductive field region and a first conductive feature. The bonded structure can include a second element that includes a second non-conductive field region and a second conductive feature. The second element directly bonded to the first element along a bonding interface such that the first non-conductive field region is directly bonded to the second non-conductive field region without an intervening adhesive. The first conductive feature is directly bonded to the second conductive feature without an intervening adhesive. A first portion of the first non-conductive field region at the bonding interface has a first surface roughness, and a second portion of the first non-conductive field region at the bonding interface has a second surface roughness different from the first surface roughness.

In one embodiment, a difference between the first surface roughness and the second roughness is at least 20 Å rms.

In one embodiment, the first surface roughness of the first portion is in a range of 6 Å rms to 200 Å rms.

In one embodiment, the first surface roughness of the first portion is in a range of 20 Å rms to 200 Å rms.

In one embodiment, the second surface roughness of the second portion of the first non-conductive field region is less than 6 Å rms.

In one embodiment, the first element is a wafer or an integrated device die. The second element can be a wafer or an integrated device die.

In one aspect, a bonded structure is disclosed. The bonded structure can include a first element that includes a first non-conductive field region and a first conductive feature. The bonded structure can include a second element that includes a second non-conductive field region and a second conductive feature. The second element is directly bonded to the first element along a bonding interface such that the first non-conductive field region is directly bonded to the second non-conductive field region without an intervening adhesive. The first conductive feature is directly bonded to the second conductive feature without an intervening adhesive. At least a portion of the first non-conductive field region at the bonding interface has a surface roughness in a range of 35 Å rms to 200 Å rms.

In one embodiment, the surface roughness of the portion of the first non-conductive field region is in a range of 55 Å rms to 200 Å rms.

In one embodiment, the surface roughness of the portion of the first non-conductive field region is in a range of 100 Å rms to 200 Å rms.

In one embodiment, a surface roughness of a second portion of the first non-conductive field region is less than the surface roughness of the portion of the first non-conductive field region. The surface roughness of the second portion of the first non-conductive field region can be less than 6 Å rms.

In one embodiment, the first element is a wafer or an integrated device die. The second element can be a wafer or an integrated device die.

In one aspect, an element that is configured to bond to another element is disclosed. The element can include a non-conductive field region that has a surface at least partially defining a bonding surface. The surface of the non-conductive field region includes a first portion and a second portion. A first surface roughness of the first portion is different from a second surface roughness of the second portion. The element can include a conductive feature that is at least partially embedded in the nonconductive field region. The conductive feature has a surface at least partially defining the bonding surface. The bonding surface is configured to bond to another bonding surface of the other element without an intervening adhesive.

In one embodiment, a difference between the first surface roughness and the second roughness is at least 20 Å rms.

In one embodiment, the first surface roughness of the first portion is in a range of 6 Å rms to 200 Å rms.

In one embodiment, the first surface roughness of the first portion is in a range of 35 Å rms to 200 Å rms.

In one embodiment, the second surface roughness of the second portion of the first non-conductive field region is less than 6 Å rms.

In one embodiment, the first element is a wafer or an integrated device die. The second element can be a wafer or an integrated device die.

In one aspect, an element that is configured to bond to another element is disclosed. The element can include a non-conductive field region that has a surface at least partially defining a bonding surface. At least a portion of the surface of the non-conductive field region has a surface roughness in a range of 35 Å rms to 200 Å rms. The element can include a conductive feature proximate to the nonconductive field region. The conductive feature has a surface at least partially defining the bonding surface. The bonding surface is configured to bond to another bonding surface of the other element without an intervening adhesive.

In one embodiment, the surface roughness of the portion of the non-conductive field region is in a range of 55 Å rms to 200 Å rms.

In one embodiment, the surface roughness of the portion of the non-conductive field region is in a range of 100 Å rms to 200 Å rms.

In one embodiment, a surface roughness of a second portion of the surface of the non-conductive field region is less than the surface roughness of the portion of the first non-conductive field region. The surface roughness of the second portion of the first non-conductive field region is less than 6 Å rms.

In one embodiment, the first element is a wafer or an integrated device die. The second element is a wafer or an integrated device die.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of forming a bonded structure, the method comprising:
polishing a surface of a first element to form a polished surface;
roughening at least a portion of the polished surface of the first element to form a bonding surface having a roughened surface with a surface roughness of at least 10 Å rms; and
directly bonding the bonding surface of the first element to a bonding surface of a second element.

2. The method of claim 1, wherein the first element comprises a non-conductive field region and a conductive feature at the bonding surface.

3. The method of claim 2, wherein polishing the surface comprises polishing the non-conductive field region to a surface roughness of 6 Å rms or less.

4. The method of claim 3, wherein roughening comprises roughening a portion of the non-conductive field region to a surface roughness at least 20 Å rms.

5. The method of claim 2 wherein the entire polished surface of the non-conducive field region is roughened.

6. The method of claim 2 wherein the second element comprises a non-conductive field region and a conductive feature, wherein the non-conductive field region of the first element and the non-conductive field region of the second element are directly bonded to one another without an intervening adhesive.

7. The method of claim 6, wherein the conducive feature of the first element and the conductive feature of the second element are directly bonded to one another without an intervening adhesive.

8. The method of claim 1, further comprising polishing a surface of the second element to define the bonding surface of the second element.

9. The method of claim 1, further comprising polishing a surface of the second element to define a polished surface of the second element, and roughening at least a portion of the polished surface of the second element to define the bonding surface of the second element that includes a roughened surface.

10. The method of claim 1, wherein roughening the portion of the polished surface comprises patterning a masking structure over the polished surface.

11. The method of claim 10, wherein the masking structure comprises a photoresist layer or a passivation layer.

12. The method of claim 10, further comprising removing the masking structure.

13. The method of claim 12, further comprising providing a protective layer over the roughened surface of the first element.

14. The method of claim 13, further comprising singulating the first element into a plurality of singulated elements and removing the protective layer from the singulated elements.

15. The method of claim 13, wherein directly bonding includes initially contacting an edge portion of the bonding surface of the first element to the bonding surface of the second element such that the bonding surface of the first element is angled in a range of 1° to 15° relative to the bonding surface of the second element.

16. A method of forming a bonding surface for direct bonding, the method comprising:
providing an element having a polished surface including a non-conductive field region and a conductive feature; and
roughening at least a portion of non-conductive field region of the polished surface.

17. The method of claim 16, further comprising polishing a surface of the element to form the polished surface.

18. The method of claim 16, wherein the polished surface has a surface roughness of 6 Å rms or less.

19. The method of claim 16, wherein roughening the portion of the non-conductive field region comprises forming a roughened surface having a surface roughness greater than 6 Å rms.

20. The method of claim 19, wherein the surface roughness of the roughened surface is in a range of 35 Å rms to 200 Å rms.

21. The method of claim 16, further comprising patterning a masking structure over the polished surface before roughening.

22. The method of claim 21, further comprising removing the masking structure after roughening.

23. The method of claim 21, further comprising providing a masking structure over the roughened surface of the first element.

24. The method of claim 21, wherein the masking structure comprises a photoresist layer or a passivation layer.

25.-52. (canceled)
